(19) United States
(12) Patent Application Publication
(10) Pub. No.: US 2025/0284211 A1
(43) Pub. Date: Sep. 11, 2025

(54) SWITCHABLE SUPPORTING MECHANISM AND RETICLE CONTAINER APPLYING THE SAME

(71) Applicant: GUDENG PRECISION INDUSTRIAL CO., LTD., NEW TAIPEI (TW)

(72) Inventors: Ming-Chien Chiu, NEW TAIPEI (TW); CHIA-HO CHUANG, NEW TAIPEI (TW); Hsin-Min HSUEH, NEW TAIPEI (TW); Pin-Cheng CHEN, NEW TAIPEI (TW); Yen-Cheng TU, NEW TAIPEI (TW); Ya-Shi WANG, NEW TAIPEI (TW)

(21) Appl. No.: 19/070,659

(22) Filed: Mar. 5, 2025

Related U.S. Application Data
(60) Provisional application No. 63/561,362, filed on Mar. 5, 2024.

(51) Int. Cl. G03F 7/00; G03F 1/66; H01L 21/673

(52) U.S. Cl. CPC G03F 7/70741; G03F 1/66; H01L 21/67359

(57) ABSTRACT

A switchable supporting mechanism adapted for an inner pod base of a dual pod. A switch of an electrostatic discharge (ESD) conduction path is established between the switchable supporting mechanism and the inner pod base. At an instant that a support of the switchable supporting mechanism is pressed downward by a reticle and comes into contact with the inner pod base, the electrostatic discharge conduction path is closed immediately to discharge electrostatic charge accumulated on a front surface of the reticle. In contrast, when the support is not in contact with the inner pod base, the electrostatic discharge conduction path opens. Therefore, the arcing phenomenon due to a voltage difference between electrostatic charge of the reticle and a conventional supporting mechanism can be prevented, and numerous problems such as carbon pollution (C-burst) and damage caused by electrical breakdown of the support can be solved.

### CROSS-REFERENCE TO RELATED APPLICATIONS

This application claims priority to U.S. Provisional Patent Application No. 63/561,362 filed in U.S. on Mar. 5, 2024 the entire contents of which are hereby incorporated by reference.

### BACKGROUND OF THE INVENTION

### Field of the Invention

The present disclosure relates to a supporting mechanism of a reticle container, and more particularly to a switchable supporting mechanism and a reticle container applying the same.

### DESCRIPTION OF THE PRIOR ART

A front surface of an extreme ultraviolet (EUV) reticle may carry residual static electricity (for example, positive charge) during exposure of the EUV reticle. An existing reticle support is fixed in an inner pod (EUV inner pod (EIP)) of the reticle container, and is configured to provide electrostatic discharge (ESD). When the inner pod is placed in a scanning machine and is opened, the support, an inner pod base and an apparatus arm are electrically connected to one another and are coupled to ground, hence forming an electrical conduction path. In this case, at an instant that the reticle is placed back into the inner pod base and comes into contact with the support, the residual static electricity on the surface of the reticle is discharged via the electrical conduction path.

For a reticle having undergone multiple rounds of exposure, charge is continually accumulated so a large amount of charge is present on the surface of the reticle. While such reticle is being placed back into the inner pod base designed with electrostatic discharge, due to an overly large voltage between the reticle and the support as well as the principle of attraction between positive and negative electricity, an arcing phenomenon may easily occur when the reticle approaches the support. As a result, the support may be subject to electrical breakdown, causing related problems such as carbon pollution (C-burst) and damage of the support.

If the support is in entirety made of an insulating material (without any electrostatic discharge ability), the static electricity accumulated on the reticle cannot be discharged via any path, forming an extremely large potential difference between the reticle and the support. Under the conditions above, in case of any residual substance of a reticle metal coating on the surface of the support, arcing may occur easily to lead to damage much severer than that caused when a support made of an electrostatic discharge material is used. Therefore, there is a need for a solution for solving the problem of arcing and for effectively solving the problem of electrostatic charge on a reticle.

### SUMMARY OF THE INVENTION

In view of the problems above, the present disclosure provides a switchable supporting mechanism adapted for an inner pod base of a dual pod. The switchable supporting mechanism includes: a base, arranged on the inner pod base; a support, having an electrostatic discharge (ESD) material, the support inserting through the base to get close to the inner pod base; and an insulating separator, for separating a contact between the base and the support to cause the support to reciprocate relative to the base, such that the support comes into contact with the inner pod base to establish an electrostatic discharge conduction path, or such that a gap is kept between the support and the inner pod base to disconnect the electrostatic discharge conduction path.

In a specific embodiment, when the support does not receive any external force, the support departs from the inner pod base such that the gap is kept between the support and the inner pod base to disconnect the electrostatic discharge conduction path; when the support receives an external force, the support comes into contact with the inner pod base to establish the electrostatic discharge conduction path.

In a specific embodiment, the base includes a mounting portion and a mounting hole penetrating the mounting portion and the base, and the insulating separator includes an abutting portion and a connecting portion. The abutting portion abuts against an upper surface of the mounting portion, and the connecting portion fixes the insulating separator to the mounting portion via the mounting hole.

In a specific embodiment, the support includes a carrying portion, a contact portion, a pin portion located between the carrying portion and the contact portion, and the insulating separator has a through hole in communication with the mounting hole. The pin portion is inserted into the through hole and the mounting hole, such that the contact portion is adjacent to the inner pod base and the carrying portion is located on an upper surface of the abutting portion.

In a specific embodiment, the insulating separator includes at least one mounting structure located outside the connecting portion. The mounting structure passes through an extension expansion hole of the mounting hole and is fixed on a lower surface of the mounting portion.

In a specific embodiment, the upper surface of the mounting portion is provided with a mounting groove, the connecting portion of the insulating separator is arranged in the mounting groove, and the abutting portion abuts against an upper surface of a periphery of the mounting groove such that the insulating separator is fixed in the mounting portion.

In a specific embodiment, the insulating separator is made of an elastic material, such that when an external force is applied to or released from the support, the insulating separator is accordingly elastically compressed and deformed or elastically released and reset to cause the support to reciprocate.

In a specific embodiment, an insulating anti-detachment element is further included. The insulating anti-detachment element is arranged between the base and the support to prevent the support from departing from between the base and the insulating separator.

In a specific embodiment, the support includes a carrying portion, a contact portion, a pin portion located between the carrying portion and the contact portion, and the insulating anti-detachment element sleeves the pin portion. In a specific embodiment, the base includes a mounting portion and a mounting hole penetrating the mounting portion and the base, and an upper surface of the mounting portion is provided with a mounting groove. The support includes a carrying portion, a contact portion, and a pin portion located between the carrying portion and the contact portion. The insulating separator is arranged in the mounting groove and has a through hole in communication with the mounting hole, and the pin portion is inserted into the through hole and the mounting hole, such that the contact portion is adjacent to the inner pod base and a lower surface of the carrying portion is located on an upper surface of the insulating separator.

In a specific embodiment, an electrostatic discharge element is further arranged at a top and/or a bottom of the support.

In a specific embodiment, the support and the inner pod base establish the electrostatic discharge conduction path, which is connected to an apparatus arm to release electrostatic charge to the ground via the apparatus arm.

### BRIEF DESCRIPTION OF THE DRAWINGS

Reference can be made to the drawings and description below to better understand the present disclosure. Non-limiting and non-exhaustive embodiments are described with reference to the drawings below. It should be noted that the components in the drawings are not necessarily drawn according to their actual sizes, and are depicted to focus on the description of structures and principles.

FIG. 1 is a perspective diagram provided with an inner pod base according to an embodiment of the present disclosure.

FIG. 2 is a partial enlarged diagram of area A in FIG. 1.

FIG. 3 is an exploded diagram of a supporting mechanism according to a first embodiment of the present disclosure.

FIG. 4A is a cross-sectional schematic diagram of the supporting mechanism according to the first embodiment of the present disclosure taken along line aa in FIG. 2 when an electrostatic discharge conduction path is not formed.

FIG. 4B is a cross-sectional schematic diagram of the supporting mechanism according to the first embodiment of the present disclosure taken along the line aa in FIG. 2 when an electrostatic discharge conduction path is formed.

FIG. 5 is an exploded diagram of a supporting mechanism according to a second embodiment of the present disclosure.

FIG. 6A is a cross-sectional schematic diagram of the supporting mechanism according to the second embodiment of the present disclosure when an electrostatic discharge conduction path is not formed.

FIG. 6B is a cross-sectional schematic diagram of the supporting mechanism according to the second embodiment of the present disclosure when an electrostatic discharge conduction path is formed.

FIG. 7 is an exploded diagram of a supporting mechanism according to a third embodiment of the present disclosure.

FIG. 8A is a cross-sectional schematic diagram of the supporting mechanism according to the third embodiment of the present disclosure when an electrostatic discharge conduction path is not formed.

FIG. 8B is a cross-sectional schematic diagram of the supporting mechanism according to the third embodiment of the present disclosure when an electrostatic discharge conduction path is formed.

FIG. 9A is a cross-sectional schematic diagram of the supporting mechanism of a first variation example of the present disclosure when an electrostatic discharge conduction path is not formed.

FIG. 9B is a cross-sectional schematic diagram of the supporting mechanism of the first variation example of the present disclosure when an electrostatic discharge conduction path is formed.

FIG. 10A is a cross-sectional schematic diagram of the supporting mechanism of a second variation example of the present disclosure when an electrostatic discharge conduction path is not formed.

FIG. 10B is a cross-sectional schematic diagram of the supporting mechanism of the second variation example of the present disclosure when an electrostatic discharge conduction path is formed.

FIG. 11A is a cross-sectional schematic diagram of the supporting mechanism of a third variation example of the present disclosure when an electrostatic discharge conduction path is not formed.

FIG. 11B is a cross-sectional schematic diagram of the supporting mechanism of the third variation example of the present disclosure when an electrostatic discharge conduction path is formed.

### DETAILED DESCRIPTION OF THE EMBODIMENTS

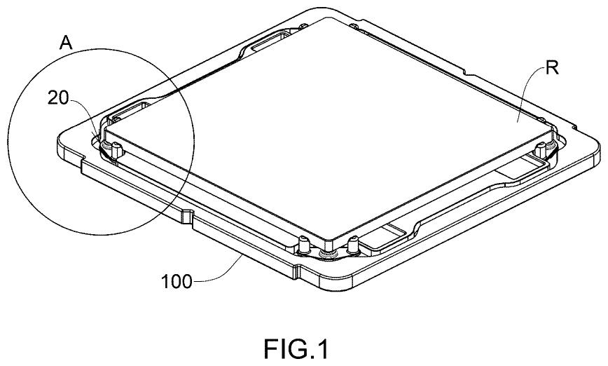

Referring to FIG. 1, the present disclosure provides a reticle container having a reticle supporting mechanism with a switchable electrostatic discharge (ESD) path. The reticle container is a dual pod, and includes an outer pod and an inner pod accommodated in the outer pod. The reticle supporting mechanism of the present disclosure is adapted for a base of the inner pod. In the embodiment in FIG. 1, an inner pod base 100 included in the inner pod is shown while a cover of the inner pod is omitted. The inner pod base 100 provides multiple supporting mechanisms 20 for carrying a reticle R.

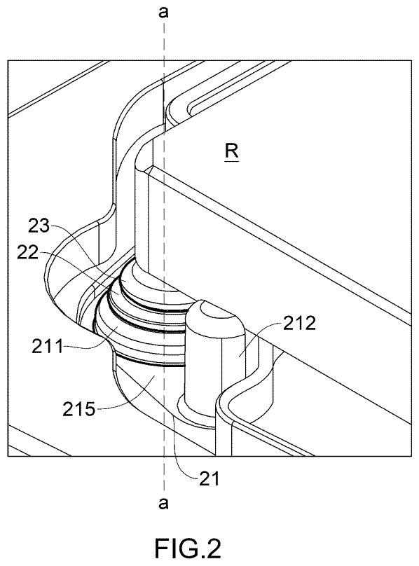

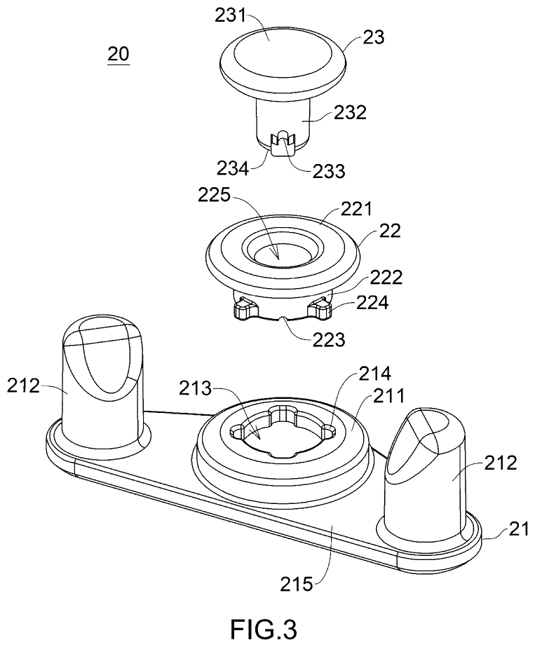

Referring to FIG. 2, four corners of the reticle R respectively correspond to the four supporting mechanisms 20. The inner pod base 100 of this embodiment has a groove in which the supporting mechanisms 20 are arranged. The present disclosure does not define that the inner pod base 100 necessarily has a groove, and regions for placing the reticle and arranging the supporting mechanisms 20 may be coplanar. The supporting mechanism 20 includes a base 21, an insulating separator 22 and a support 23. The base 21 is arranged at the inner pod base 100 of the reticle container, the insulating separator 22 is arranged on the base 21, and the support 23 is arranged adjacent to the inner pod base 100 via the insulating separator 22 and functions as a switch of an electrostatic discharge path. The reticle R is placed on the support 23. The insulating separator 22 is located between the support 23 and the base 21, and is for separating a contact between the base 21 and the support 23 to maintain electrical disconnection between the base 21 and the support 23. The insulating separator 22 determines whether the support 23 and the inner pod base 100 are to come into contact with each other. In a non-deformed state of the insulating separator 22, the support 23 and the inner pod base 100 are not in direct contact with each other. In a deformed state of the insulating separator 22, the support 23 and the inner pod base 100 are in direct contact with each other, with associated details described below. Refer to FIG. 3 showing an exploded diagram of the supporting mechanism 20 according to a first embodiment of the present disclosure. The base 21 includes a seat 215, a limiting portion 212 and a mounting portion 211. This embodiment includes two limiting portions 212 respectively extending upward from two ends of the seat 215. The mounting portion 211 bulges upwards from the seat 215. The mounting portion 211 has a mounting hole 213 at a center thereof, wherein the mounting hole 213 penetrates the seat 215 and the mounting portion 211 such that the insulating separator 22 is arranged in the mounting hole 213.

The insulating separator 22 is substantially made of an electrically insulative and elastic material. When an external force is applied to or released from the support 23, the insulating separator 22 is accordingly elastically compressed and deformed or elastically released and reset to cause the support 23 to reciprocate. The insulating separator 22 includes an abutting portion 221 and a connecting portion 222. The connecting portion 222 can couple the insulating separator 22 to the seat 21 via the mounting hole 213, and the abutting portion 221 abuts against an upper surface of the mounting portion 211 at this point in time. Moreover, the abutting portion 221 is configured between the mounting portion 211 and a portion of the support 23. The insulating separator 22 further includes a through hole 225. The through hole 225 penetrates upper and lower surfaces of the insulating separator 22, and corresponds to a position of the mounting hole 213 to communicate with each other. A portion of the support 23 is inserted into the through hole 225 and the mounting hole 213. In this embodiment, the insulating separator 22 further includes a mounting structure 224 protruding outward from a surface of the connecting portion 222. The mounting hole 213 has an extension expansion hole 214 corresponding to the mounting structure 224, for the mounting structure 224 to pass through and for the insulating separator 22 to be mounted in the mounting hole 213. Preferably, a lower edge of the insulating separator 22 further includes an engaging portion 223 for engaging the support 23 with the insulating separator 22, so as to prevent the support 23 from departing upward.

The support 23 has an electrostatic discharge material. The support 23 includes a carrying portion 231, a contact portion 234, and a pin portion 232 arranged between the carrying portion 231 and the contact portion 234. The carrying portion 231 is for carrying the reticle R and may have an arc or a pattern, such that the carrying portion 231 and the reticle R are in point contact to reduce the contact area of the reticle R and reduce dust generation. The pin portion 232 passes through the through hole 225 of the insulating separator 22 to have the support 23 being adjacent to the insulating separator 22. The contact portion 234 of the support 23 is then placed into the mounting hole 213 to a position near the inner pod base 100. The carrying portion 231 is located on an upper surface of the abutting portion 221.

The supporting mechanism 20 further includes an insulating anti-detachment element 233 arranged between the seat 21 and the support 23. In this embodiment, the insulating anti-detachment element 233 is arranged at the pin portion 232 of the support 23, and the insulating anti-detachment element 233 and the engaging portion 223 of the insulating separator 22 may be engaged with each other to prevent the support 23 from departing from the insulating separator 22. Moreover, since the insulating separator 22 is fixed on the seat 21 via the abutting portion 221 and the mounting structure 224, the support 23 can be prevented from departing from the seat 21 and the insulating separator 22 by means of interlocking connection. The insulating anti-detachment element 233 is adapted for any form of the insulating separator, and can be matched and combined as desired and is not limited to the form disclosed in this embodiment.

In continuation from the description of the supporting mechanism 20 above, when the supporting mechanism 20 is applied to the inner pod base 100, the seat 21 may be fixed on the inner pod base 100 by any conventional means. Next, the mounting structure 224 of the insulating separator 22 is aligned with and placed into the extension expansion hole 214 of the mounting hole 213 of the seat 21, and the insulating separator 22 is rotated to mismatch the mounting structure 224 and the extension expansion hole 214, such that the insulating separator 22 is fixed to the seat 21. Lastly, the support 23 is placed into the through hole 225 of the insulating separator 22, and an external force is slightly applied to have the insulating anti-detachment element 233 pass through a lower edge of the insulating separator 22 and be engaged with the engaging portion 223. At this point in time, the contact portion 234 of the support 23 protrudes outside the mounting hole 214 of the seat 21, and is adjacent to the inner pod base 100. The mounting sequences include but are not limited to the steps above, and the mounting sequences of the elements can be adjusted according to requirements.

In this embodiment, the support 23 and the seat 21 have an electrostatic discharge function, and can be, for example, made of an electrostatic discharge material or have surfaces coated with an electrostatic discharge coating material; the insulating separator 22 is made of an insulating material or has a surface coated with an insulating coating material. Preferably, surface resistivities of the support 23 and the seat 21 range between 10⁴ Ω/sq and 10¹⁰ Ω/sq, and a surface resistivity of the insulating separator 22 is equal to or greater than 10¹⁰ Ω/sq. In this embodiment, the material forming the insulating separator 22 may include polyethylene (PE), polypropylene (PP), polyethylene terephthalate (PET), thermoplastic elastomer (TPR), thermoplastic polyester elastomer (TPEE), fluorinated rubber (FKM), or any combination of the above. The materials forming the support 23 and the seat 21 may include polyetheretherketone (PEEK), polyimide (PI), or any combination of the above.

The insulating separator 22 has an elastic structure. When a downward pressure (or referred to as an external force) generated by placing a reticle is applied to the support 23, the insulating separator 22 receives the abutment between the seat 21 and the support 23 and produces elastic structural deformation such as elastic compression deformation, such that the support 23 can reciprocate and move downward relative to the seat 21 until the contact portion 234 comes into contact with the inner pod base 100 so as to establish an electrostatic discharge conduction path. The electrostatic charge on the reticle can be electrostatically discharged via the support 23 to the inner pod base 100. When the inner pod base 100 is located within a scanning machine, the scanning machine is provided with an apparatus arm and is grounded. Once the inner pod base 100 comes into contact with the apparatus arm, it may form one of the electrostatic discharge conduction paths via the apparatus arm and the ground and thus has an electrostatic discharge function.

When a reticle is removed from the support 23 or when no reticle is placed on the support 23, the insulating separator 22 is not subject to the abutment between the seat 21 and the support 23, and is elastically released at this point in time to restore its original elastic height, such that a gap d is kept between the contact portion 234 of the support 23 and the inner pod base 100 to disconnect the electrostatic discharge conduction path. In a specific embodiment, by separating the contact between the seat 21 and the support 23 by the insulating separator 22 and according to whether the support 23 receives an external force, it is determined whether the support 23 and the inner pod base 100 are to come into contact with each other, accordingly achieving the technical effect and object of the switch for establishing an electrostatic discharge conduction path between the supporting mechanism 20 and the inner pod base 100.

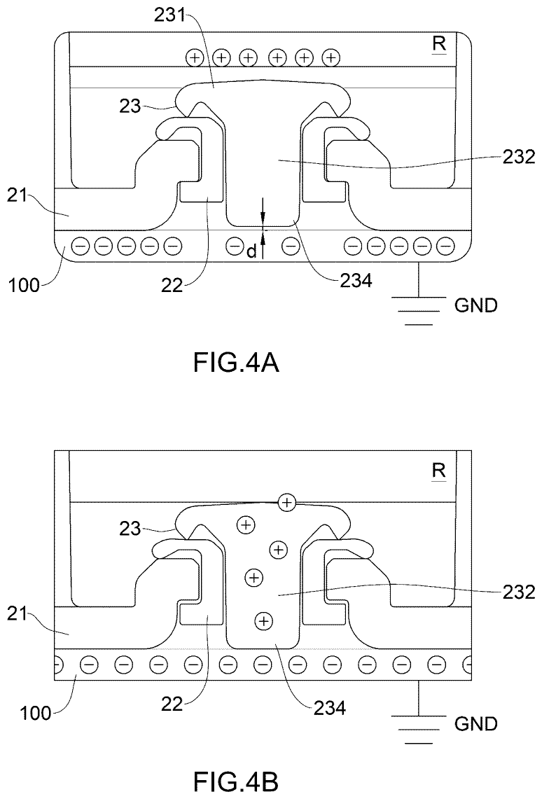

In continuation of the description above, referring to FIG. 4A, after exposure, a front surface of the reticle R carries residual electrostatic charge, for example, positive charge. When the support 23 does not receive any external force of a downward pressure from the reticle R, the gap d is present between the support 23 and the inner pod base 100. At this point in time, the support 23 lacks an ability of attracting the electrostatic charge on the front surface of the reticle R, and thus does not conduct any electricity through the ground GND. In other words, the support 23 cannot attract the positive electricity of the reticle R from a ground terminal to the ground GND, and thus the electrostatic discharge conduction path is disconnected at this point in time.

Referring to FIG. 4B, when the reticle R is placed at the support 23, the support 23 receives an external force and is pushed downward to force the insulating separator 22 to become elastically deformed until surfaces of the contact portion 234 of the support 23 and the inner pod base 100 are in contact with each other. At this point in time, the electrostatic discharge conduction path is formed. At this point in time, the support 23 has an ability of attracting the electrostatic charge on the front surface of the reticle R, and an electrostatic discharge conduction path along the support 23, the inner pod base 100 and the ground GND is established to discharge electrostatic charge of the reticle R.

By establishing the switch of an electrostatic discharge conduction path, the object of the present disclosure is to solve the numerous problems of an arcing phenomenon due to a voltage difference when a reticle with a large amount of static electricity accumulated on a surface thereof approaches a supporting mechanism, as well as carbon pollution (C-burst) and damage caused by electrical breakdown of the supporting mechanism. Moreover, an effect of quickly electrostatically discharging the residual static electricity on the surface of a reticle after exposure can be achieved.

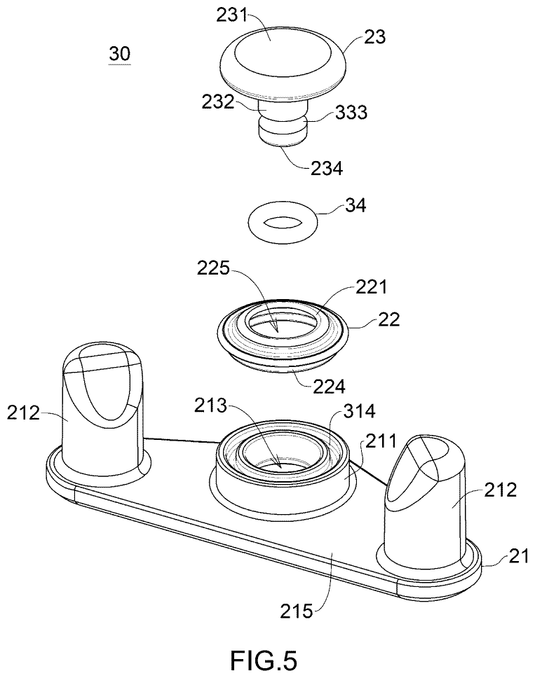

FIG. 5 shows a supporting mechanism 30 according to a second embodiment of the present disclosure. In the supporting mechanism 30, the elements denoted by the same numerals as the supporting mechanism 20 of the first embodiment have the same functions, and only structural differences are described below. The supporting mechanism 30 includes the seat 21, the insulating separator 22, an insulating anti-detachment element 34 and the support 23. A groove 314 is provided annularly on an upper surface of the mounting hole 213. The through hole 225 penetrates the upper and lower surfaces of the insulating separator 22, and corresponds to the position of the mounting hole 213 to communicate with each other. A portion of the support 23 is inserted in the through hole 225 and the mounting hole 213.

A top of the insulating separator 22 has the abutting portion 221 made of an electrically insulative and elastic material, and causes the support 23 to reciprocate relative to the seat 21 when an external force is applied to or released from the support 23. The connecting portion 222 of the insulating separator 22 corresponds in shape to the groove 314, and the two can be mutually installed and fixed so as to couple the insulating separator 22 and the seat 21 with each other. In this embodiment, the insulating anti-detachment element 34 is an annular member made of an elastic material, and the pin portion 232 of the support 23 has a groove 333 around a surface thereof, such that the insulating anti-detachment element 34 sleeves the groove 333.

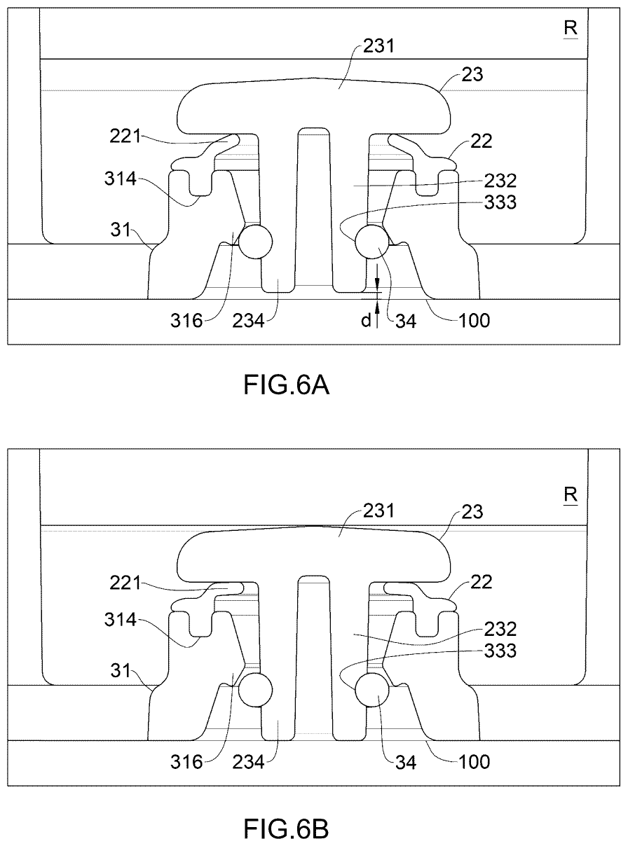

Referring to both FIG. 6A and FIG. 6B, a seat 31 is provided with a limiting structure 316 located inside the mounting hole 213 to abut against the insulating anti-detachment element 34. Once the pin portion 232 of the support 23 is inserted into the through hole 225 of the insulating separator 22 and the mounting hole 213 of the seat 31, the limiting structure 316 abuts against the insulating anti-detachment element 34 to prevent disengagement of the support 23. Since the support 23 functions as a switch of an electrostatic discharge path, when an external force is applied to or released from the support 23, the insulating separator 22 is accordingly elastically compressed and deformed or elastically released and reset to cause the support 23 to reciprocate. As shown in FIG. 6A, the insulating separator 22 is elastically released to restore its original elastic height, such that the gap d is kept between the contact portion 234 of the support 23 and the inner pod base 100 to open the electrostatic discharge conduction path. To prevent the support 23 from moving upward and departing from one or both of the base 31 and the insulating separator 22, the limiting structure 316 is used to abut against and restrict the insulating anti-detachment element 34 and to keep the insulating anti-detachment element 34 in the mounting hole 213, further preventing the support 23 from moving excessively upward and hence preventing the pin portion 232 from falling out of the mounting hole 213.

As shown in FIG. 6B, the insulating separator 22 is configured to allow the support 23 to move downward relative to the base 21 until the contact portion 234 comes into contact with the inner pod base 100, so as to establish the electrostatic discharge conduction path. At this point in time, the limiting structure 316 does not abut against the insulating anti-detachment element 34. Moreover, because the insulating anti-detachment element 34 sleeves the groove 333 such that it moves downward along with the support 23, the smoothness of reciprocation of the support 23 is unaffected.

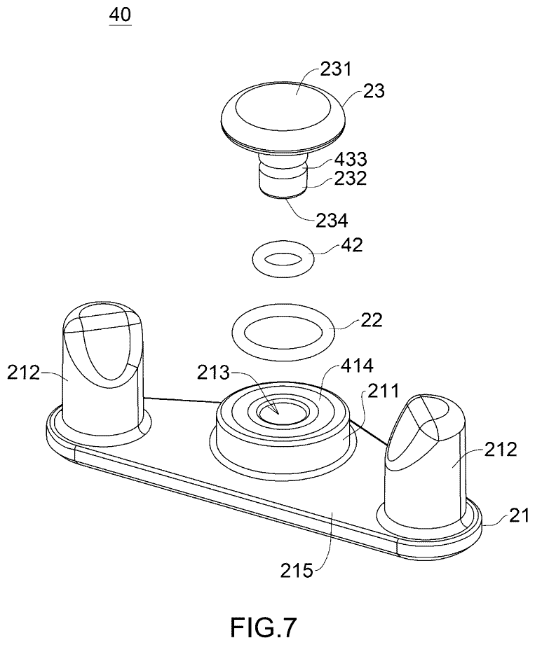

FIG. 7 shows a supporting mechanism 40 according to a third embodiment of the present disclosure. In the supporting mechanism 40, the elements denoted by the same numerals as the supporting mechanism 20 of the first embodiment and the supporting mechanism 30 of the second embodiment have the same functions, and only structural differences are described below. The insulating separator 22 has an electrically insulative and elastic material, and is an annular member. An upper surface of the insulating separator 22 is defined as the abutting portion 221, and the connecting portion 222 is defined between the upper surface and the lower surface. The connecting portion 222 of the insulating separator 22 corresponds in shape to a groove 414, and the two can be mutually installed and fixed so as to couple the insulating separator 22 and the seat 21 with each other. The abutting portion 221 is configured between the mounting portion 211 and the support 23. The insulating anti-detachment element 42 is an annular member made of an elastic material, and the pin portion 232 of the support 23 has a groove 433 around a surface thereof, and the insulating anti-detachment element 42 is for sleeving the groove 433. The support 23 is placed into an annular hollow of the insulating separator 22 in a direction toward the seat 21, and a slight external force is applied to push the insulating anti-detachment element 42 to below a limiting structure 416, such that the support 23 and the seat 21 become coupled with each other via the insulating separator 22. When an external force is applied to or released from the support 23, the elastic deformation of the insulating separator 22 causes the support 23 to reciprocate relative to the seat 21.

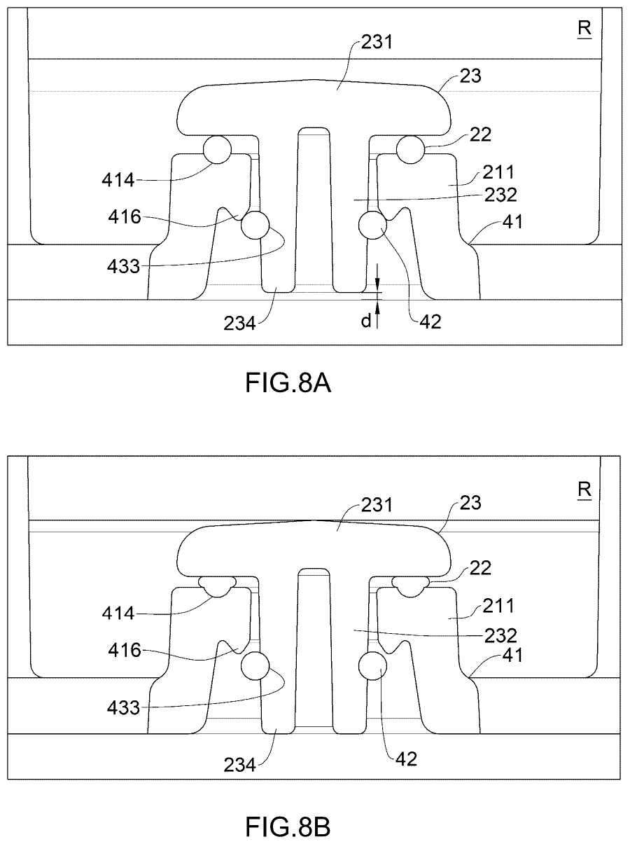

Referring to FIG. 8A, when the reticle R is not yet placed on the support 23, because the insulating separator 22 is not yet compressed or deformed and is maintained with its original shape and height, the insulating anti-detachment element 42 abuts against below the limiting structure 416, such that the support 23 cannot move upward and the support 23 is not in contact with the inner pod base 100 at this point in time. The gap d is present between the contact portion 234 of the support 23 and the surface of the inner pod base 100. At this point in time, the electrostatic discharge conduction path between the support 23 and the inner pod base 100 is disconnected. When the electrostatic discharge conduction path of the supporting mechanism 40 is disconnected, despite that residual static electricity exists on the surface of the reticle R after exposure, the arcing phenomenon does not occur if the reticle R approaches the support 23 at this point in time, and pollution caused by arcing can be prevented.

Referring to FIG. 8B, when the reticle R is placed at the support 23, the support 23 receives an external force of a downward pressure by the reticle R and is pushed downward to force the insulating separator 22 to become compressed or deformed to allow the support 23 to move downward relative to the base 21, and the insulating anti-detachment element 42 also moves downward along with the support 23 until surfaces of the contact portion 234 of the support 23 and the inner pod base 100 are in contact with each other. At this point in time, the electrostatic discharge conduction path between the bottom of the support 23 and the inner pod base 100 is formed. When the electrostatic discharge conduction path of the supporting mechanism 40 is formed, the positive charge on the surface of the reticle R is discharged through a path along the support 23, the inner pod base 100, the apparatus arm and the ground (not shown).

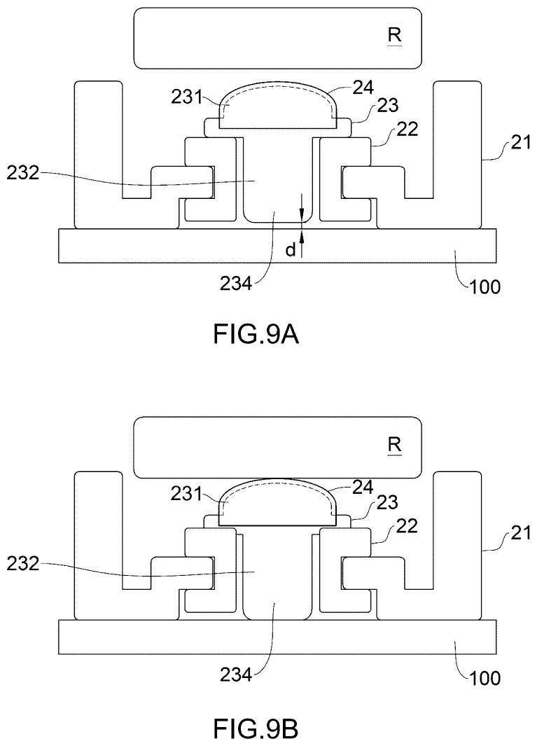

In a variation example of the present disclosure, in addition to being in entirety made of an electrostatic discharge material, the support 23 can also be partially made of electrostatic discharge material, for example, the top and/or the bottom of the support 23 is further provided with an electrostatic discharge element. FIG. 9A and FIG. 9B show a first variation example of a supporting mechanism of the present disclosure. The support 23 further includes an electrostatic discharge element 24 arranged at the top of the support 23. More specifically, the electrostatic discharge element 24 is arranged at the carrying portion 231 of the support 23 and is detachably connected to the support 23.

As shown in FIG. 9B, when the reticle R is placed on the support 23, the reticle R comes into contact with the electrostatic discharge element 24, and then the electrostatic discharge element 24 and the support 23 move downward together until the contact portion 234 of the support 23 comes into contact with the inner pod base 100. At this point in time, the positive charge on the surface of the reticle R is discharged through a path along the electrostatic discharge element 24, the support 23, the inner pod base 100, the apparatus arm and the ground (not shown).

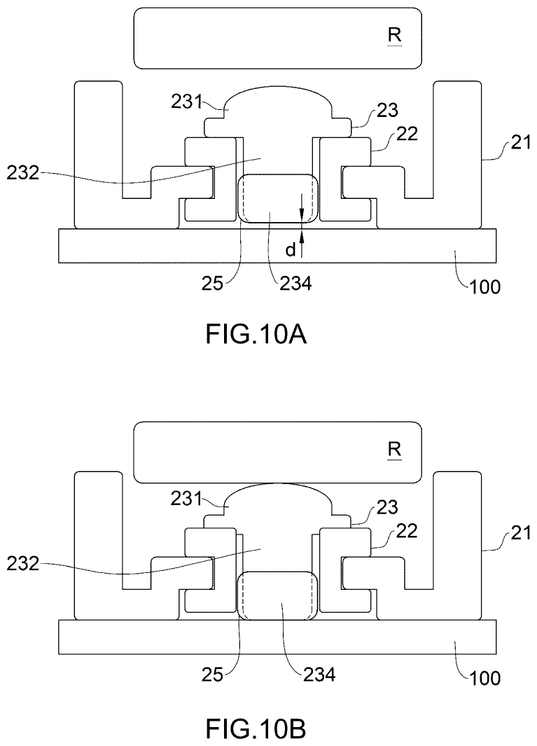

FIG. 10A and FIG. 10B show a supporting mechanism of a second variation example. The support 23 further includes an electrostatic discharge element 25 arranged at the bottom of the support 23; for example, the electrostatic discharge element 25 is provided below the contact portion 234, or the electrostatic discharge element 25 is provided on the pin portion 232 and the contact portion 234. More specifically, the electrostatic discharge element 25 is arranged at the support 23 and is detachably connected to the support 23.

As shown in FIG. 10B, when the reticle R is placed on the support 23, the reticle R first comes into contact with the support 23 and moves downward together with the support 23, such that the electrostatic discharge element 25 at the bottom of the support 23 comes into contact with the inner pod base 100. At this point in time, the positive charge on the surface of the reticle R is discharged through a path along the support 23, the electrostatic discharge element 25, the inner pod base 100, the apparatus arm and the ground (not shown).

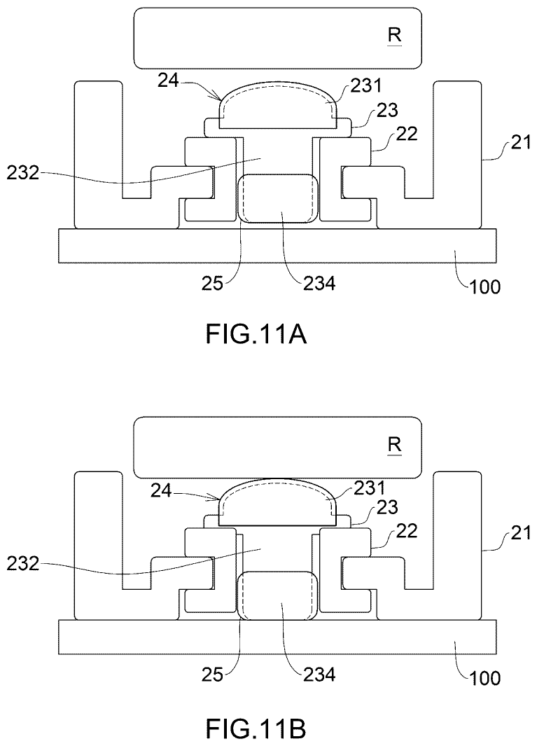

FIG. 11A and FIG. 11B show a supporting mechanism of a third variation example. The support 23 further includes a first electrostatic discharge element 24 and a second electrostatic discharge element 25 respectively arranged at the top and the bottom of the support 23. More specifically, the first electrostatic discharge element 24 is arranged at the carrying portion 231 of the support 23 and is detachably connected to the support 23. The second electrostatic discharge element 25 is arranged at the contact portion 234 of the support 23 and is detachably connected to the support 23.

As shown in FIG. 11B, when the reticle R is placed on the support 23, the reticle R comes into contact with the first electrostatic discharge element 24, and then the first electrostatic discharge element 24 and the support 23 move downward together, until the second electrostatic discharge element 25 at the bottom of the support 23 comes into contact with the inner pod base 100. At this point in time, the positive charge on the surface of the reticle R is discharged through a path along the first electrostatic discharge element 24, the support 23, the second electrostatic discharge element 25, the inner pod base 100, the apparatus arm and the ground (not shown).

By additionally arranging the electrostatic discharge elements 24 and 25 of the first to third variation examples at the support 23, the electrostatic discharge elements 24 and 25 can be easily replaced, so as to prevent wear caused by the contact between the reticle R and the carrying portion 231 of the support 23 and/or wear caused by the contact between the bottom of the support 23 and the inner pod base 100 from affecting the effect of the electrical conduction path. Regardless of how the structural design of the support 23 is modified, any support 23 functioning as a switch of an electrostatic discharge path is encompassed within the scope of the present disclosure.

What is claimed is:

1. A switchable supporting mechanism adapted for an inner pod base of a dual pod, the switchable supporting mechanism comprising:
a base, arranged on the inner pod base;
a support, having an electrostatic discharge material, the support inserting through the base to get close to the inner pod base; and
an insulating separator, selectively separating a contact between the base and the support to cause the support to reciprocate relative to the base, whereby causing the support able to come into contact with the inner pod base to establish an electrostatic discharge conduction path, or keeping a gap between the support and the inner pod base to disconnect the electrostatic discharge conduction path.

2. The switchable supporting mechanism according to claim 1, wherein when the support does not receive any external force, the support departs from the inner pod base such that the gap is kept between the support and the inner pod base to disconnect the electrostatic discharge conduction path; when the support receives an external force, the support comes into contact with the inner pod base to establish the electrostatic discharge conduction path.

3. The switchable supporting mechanism according to claim 1, wherein the base comprises a mounting portion and a mounting hole penetrating the mounting portion and the base, and the insulating separator comprises an abutting portion and a connecting portion; the abutting portion abuts against an upper surface of the mounting portion, and the connecting portion fixes the insulating separator to the mounting portion via the mounting hole.

4. The switchable supporting mechanism according to claim 3, wherein the support comprises a carrying portion, a contact portion, a pin portion located between the carrying portion and the contact portion, the insulating separator has a through hole in communication with the mounting hole, and the pin portion is inserted into the through hole and the mounting hole, such that the contact portion is adjacent to the inner pod base and the carrying portion is located on an upper surface of the abutting portion.

5. The switchable supporting mechanism according to claim 3, wherein the insulating separator comprises at least one mounting structure located outside the connecting portion, and the mounting structure passes through an extension expansion hole of the mounting hole and is fixed on a lower surface of the mounting portion.

6. The switchable supporting mechanism according to claim 3, wherein the upper surface of the mounting portion is provided with a mounting groove, the connecting portion of the insulating separator is arranged in the mounting groove, and the abutting portion abuts against an upper surface of a periphery of the mounting groove, such that the insulating separator is fixed in the mounting portion.

7. The switchable supporting mechanism according to claim 1, wherein the insulating separator is made of an elastic material, and when an external force is applied to or released from the support, the insulating separator is accordingly elastically compressed and deformed or elastically released and reset to cause the support to reciprocate.

8. The switchable supporting mechanism according to claim 1, further comprising:
an insulating anti-detachment element, arranged between the base and the support to prevent the support from departing from between the base and the insulating separator.

9. The switchable supporting mechanism according to claim 8, wherein the support comprises a carrying portion, a contact portion, a pin portion located between the carrying portion and the contact portion, and the insulating anti-detachment element sleeves the pin portion.

10. The switchable supporting mechanism according to claim 1, wherein
the base comprises a mounting portion and a mounting hole penetrating the mounting portion and the base, and a mounting groove is provided on an upper surface of the mounting portion;
the support comprises a carrying portion, a contact portion, a pin portion located between the carrying portion and the contact portion; and
the insulating separator is arranged in the mounting groove and has a through hole in communication with the mounting hole, and the pin portion is inserted into the through hole and the mounting hole, such that the contact portion is adjacent to the inner pod base and a lower surface of the carrying portion is located on an upper surface of the insulating separator.

11. The switchable supporting mechanism according to claim 1, wherein a top and/or a bottom of the support is further arranged with an electrostatic discharge element.

12. The switchable supporting mechanism according to claim 1, wherein the support and the inner pod base establish the electrostatic discharge conduction path, which is connected to an apparatus arm to release electrostatic charge to the ground via the apparatus arm.
